(19) United States
(12) Patent Application Publication
(10) Pub. No.: US 2014/0231859 A1
(43) Pub. Date: Aug. 21, 2014

(54) SEMICONDUCTOR LIGHT-EMITTING ELEMENT

(71) Applicants: Jae Yoon Kim, Yongin-si (KR); Seok Min Hwang, Pusan (KR); Su Yeol Lee, Seongnam-si (KR); Seung Wan Chae, Yongin-si (KR); Jae Ho Han, Daejeon (KR); Jin Bock Lee, Osan-si (KR)

(72) Inventors: Jae Yoon Kim, Yongin-si (KR); Seok Min Hwang, Pusan (KR); Su Yeol Lee, Seongnam-si (KR); Seung Wan Chae, Yongin-si (KR); Jae Ho Han, Daejeon (KR); Jin Bock Lee, Osan-si (KR)

(73) Assignee: SAMSUNG ELECTRONICS CO., LTD., Suwon-si, Gyeonggi-do (KR)

(21) Appl. No.: 14/236,582

(22) PCT Filed: Aug. 1, 2011
(86) PCT No.: PCT/KR2011/005655

§ 371 Date: Jan. 31, 2014

(51) Int. Cl. H01L 33/38; H01L 33/62; H01L 33/32

(52) U.S. Cl. CPC H01L 33/387; H01L 33/32; H01L 33/62
USPC 257/99

(57) ABSTRACT

A semiconductor light emitting device may include: a light emitting structure including an n-type semiconductor layer, a p-type semiconductor layer, and an active layer interposed therebetween; a first electrode connected to one of the n-type semiconductor layer and the p-type semiconductor layer; and a second electrode connected to the other of the n-type semiconductor layer and the p-type semiconductor layer. The first electrode may include a first electrode pad disposed in a central portion of one side of the light emitting structure and first to third branch electrodes connected to the first electrode pad, having a fork shape. The second electrode may include second and third electrode pads disposed separately in both corners of the other side opposing the one side and fourth to seventh branch electrodes connected thereto. The fourth and seventh branch electrodes may extend in an interdigitated manner between the first to third branch electrodes.

### TECHNICAL FIELD

The present disclosure relates to a semiconductor light emitting device and, more particularly, to a semiconductor light emitting device having an electrode structure preventing current crowding to enhance current spreading characteristics and obtain uniform light emitting characteristics.

### BACKGROUND ART

Recently, light emitting diodes (LEDs) using compound semiconductor materials such as AlGaAs, AlGaInP, AlGaInN, and the like, have been commonly used to obtain light within particular wavelength ranges. In particular, a nitride semiconductor light emitting device formed of a nitride semiconductor (generally having an empirical formula of InₓAl_{y}Ga_{1-x-y}N (0≦x≦1, 0≦y≦1, 0≦x+y≦1)) is a light source having blue, ultraviolet, and green wavelength ranges applied to a variety of products, such as an electronic display board, lighting systems, and the like. As the application fields of semiconductor LEDs have been expanded, efforts to increase luminance and luminous efficiency of semiconductor LEDs have progressed.

A nitride semiconductor light emitting device includes a light emitting structure including an n-type semiconductor layer, a p-type semiconductor layer, and an active layer interposed therebetween, and generally, the light emitting structure may be formed on a sapphire substrate. The sapphire substrate is an insulating substrate, so both of two electrodes (p-electrode and n-electrode) connected to the p-type semiconductor layer and the n-type semiconductor layer may be disposed on an upper surface of the light emitting structure. Here, a semiconductor light emitting device having such a structure in which both a p-electrode and an n-electrode are disposed on an upper surface of a light emitting structure has a current flow non-uniformly distributed in the entire light emitting region, causing current crowding, such that an effective area used for light emission is not large, resulting in low luminance efficiency.

### DISCLOSURE

### Technical Problem

An aspect of the present disclosure may provide a semiconductor light emitting device having an electrode structure having uniform current spreading characteristics and securing a large effective light emission area to obtain high luminance and high efficiency.

### Technical Solution

According to an aspect of the present disclosure, a semiconductor light emitting device may include: a light emitting structure including an n-type semiconductor layer, a p-type semiconductor layer, and an active layer interposed therebetween, and having a rectangular upper surface formed with first and second sides opposing one another and third and fourth sides opposing one another; a first electrode formed on an upper surface of the light emitting structure and connected to one of the n-type semiconductor layer and the p-type semiconductor layer; and a second electrode formed on the upper surface of the light emitting structure and connected to the other of the n-type semiconductor layer and the p-type semiconductor layer, wherein the first electrode includes a first electrode pad disposed in a central portion of the first side, a first branch electrode extending linearly from the first electrode pad toward the second side such that it is parallel to the third side; and second and third branch electrodes extending from the first electrode pad, bent toward the third and fourth sides, and extending toward the second side such that they are parallel to the first branch electrode and disposed on both sides of the first branch electrode, and the second electrode includes a second electrode pad disposed in the corner between the second side and the third side; a third electrode pad disposed in the corner between the second side and the fourth side; a fourth branch electrode extending inwardly from the second electrode pad in a bent manner and extending linearly toward the first side between the first and second branch electrodes; a fifth branch electrode extending from the second electrode pad along the third side and disposed in outer side of the second branch electrode; a sixth branch electrode extending inwardly from the third electrode pad in a bent manner and extending linearly toward the first side between the first and third branch electrodes; and a seventh branch electrode extending from the third electrode pad along the fourth side and disposed in an outer side of the third branch electrode.

The fourth to seventh branch electrodes of the second electrode may be disposed to be interdigitated with the first to third branch electrodes of the first electrode at substantially the same intervals therebetween.

The first and second electrodes may be disposed to be symmetrical based on the first branch electrode.

A line formed by connecting a center of the second electrode pad and an end portion of the second branch electrode may be at an angle ranging from 40 to 60 degrees with respect to a line extending from an end portion of the second branch electrode, and a line formed by connecting a center of the third electrode pad and an end portion of the third branch electrode may be at an angle ranging from 40 to 60 degrees with respect to a line extending from an end portion of the third branch electrode.

The fourth branch electrode may be bent to be curved from a linear line at a middle point of a segment formed by connecting the end portion of the second branch electrode and an end point of the first branch electrode, and the sixth branch electrode may be bent to be curved from a linear line at a middle point of a segment formed by connecting the end portion of the third branch electrode and an end point of the first branch electrode.

A portion in which the fourth branch electrode is led from the second electrode pad may be at an angle ranging from 100 to 180 degrees with respect to a portion in which the fifth branch electrode is led from the second electrode pad, and a portion in which the sixth branch electrode is led from the third electrode pad may be at an angle ranging from 100 to 180 degrees with respect to a portion in which the seventh branch electrode is led from the third electrode pad.

A distance between the fifth branch electrode and a lateral outer edge of the light emitting structure may range from 30% to 50% of a current spreading distance between the mutual first to seventh branch electrodes having different polarities, and a distance between the seventh branch electrode and a lateral outer edge of the light emitting structure may range from 30% to 50% of a current spreading distance between the mutual first to seventh branch electrodes having different polarities.

The second and third branch electrodes may extend, while drawing a curved line, from the first electrode pad toward the third and fourth sides, respectively, be bent, and extend linearly toward the second side.

The rounded portions of the second and third branch electrodes extending from the first electrode pad may form a circular arc based on the first electrode pad.

The rounded portions of the second and third branch electrodes extending from the first electrode pad may form two different circular arcs connected by the first electrode pad.

The end portion of the first branch electrode may extend toward the second side so as to be closer to the second side than the end portions of the second and third branch electrodes are.

The fifth and seventh branch electrodes may be bent inwardly in the vicinity of end portions thereof.

The first electrode may be an n-electrode, and the second electrode may be a p-electrode.

The semiconductor light emitting device may be a nitride-based semiconductor light emitting device.

### Advantageous Effects

According to exemplary embodiments of the present disclosure, in a semiconductor light emitting device, uniform current spreading may be obtained and current crowding in a partial region may be effectively prevented. As a result, an effective light emitting area may be increased to enhance luminance and efficiency.

### DESCRIPTION OF DRAWINGS

The above and other aspects, features and other advantages of the present disclosure will be more clearly understood from the following detailed description taken in conjunction with the accompanying drawings, in which:

FIG. 1 is a plan view illustrating a semiconductor light emitting device according to an exemplary embodiment of the present disclosure;

FIG. 2 is a cross-sectional view illustrating the semiconductor light emitting device of FIG. 1 taken along line A-A′;

FIG. 3 is a plan view illustrating a semiconductor light emitting device according to a comparison example; and

FIG. 4 is a plan view illustrating a semiconductor light emitting device according to another exemplary embodiment of the present disclosure.

### MODE FOR INVENTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

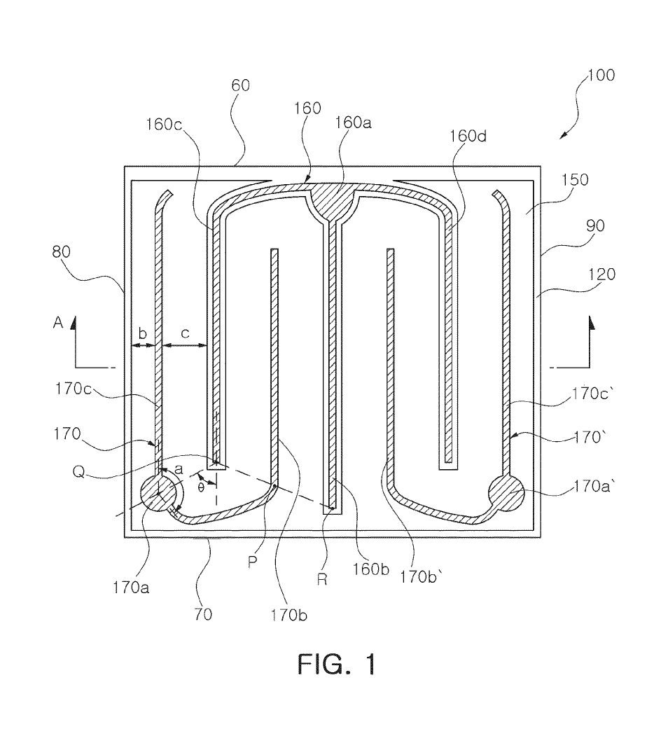

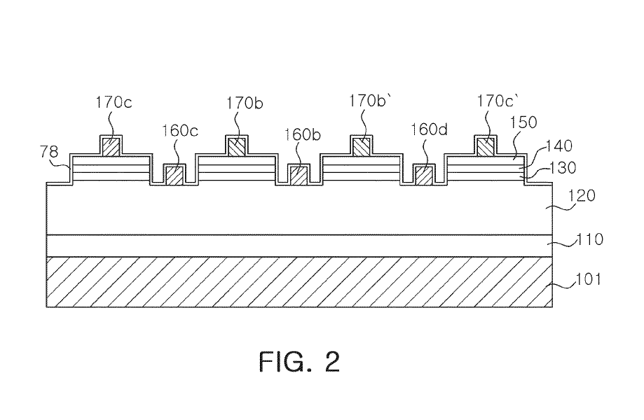

FIG. 1 is a top plan view illustrating a semiconductor light emitting device according to an exemplary embodiment of the present disclosure, and FIG. 2 is a cross-sectional view illustrating the semiconductor light emitting device of FIG. 1 taken along line A-A′. Referring to FIGS. 1 and 2, a semiconductor light emitting device 100 includes a buffer layer 110, an n-type semiconductor layer 120, an active layer 130, and a p-type semiconductor layer 140 sequentially formed on a substrate 101 formed of sapphire, for example, or the like. The n-type and p-type semiconductor layers 120 and 140 and the active layer 130 interposed therebetween form a light emitting structure. A transparent electrode layer 150 may be formed on the p-type semiconductor layer 140. In the present exemplary embodiment, the transparent electrode layer 150 is disposed, but in order to use the light emitting device for a flip chip structure, a reflective electrode layer may be disposed on an upper surface of the light emitting structure instead of the transparent electrode layer 150. The light emitting device 100 may be a nitride-based semiconductor light emitting device in which the light emitting structure (composed of the n-type semiconductor layer 120, the active layer 130, and the p-type semiconductor layer 140) is formed of a Group III-nitride semiconductive material such as GaN, AlGaN, InGaN, AlGaN, or the like.

A first electrode 160 (n-electrode in the present exemplary embodiment) is formed on a partial n-type semiconductor region exposed through mesa etching and electrically connected to the n-type semiconductor layer 120, and second electrodes (p-electrodes in the present exemplary embodiment) 170 and 170′ are formed on the transparent electrode layer 150 and electrically connected to the p-type semiconductor layer 140. As illustrated in FIG. 1, an upper surface of the light emitting structure has a rectangular shape, and the rectangular shape includes a first side 60 and a second side 70 opposing one another and a third side 80 and a fourth side 90 opposing one another.

As illustrated in FIG. 1, the first electrode 160 includes a first electrode pad 160a and three branch electrodes 160b, 160c, and 160d extending from the first electrode pad 160a. The electrode pad 160a and the branch electrodes 160b, 160c, and 160d are considered n-electrode elements in the present exemplary embodiment. In detail, the first electrode pad 160a is disposed in a central portion of the first side 60. The first branch electrode 160b extends linearly toward the second side 70 from the first electrode pad 160a and, in particular, is parallel to the third side 80 and the fourth side 90. The first branch electrode 160b may be disposed in a central portion of the light emitting structure. The second branch electrode 160c extends from the first electrode pad 160a toward the third side 80 and is bent to extend linearly toward the second side 70, facing the first electrode pad 160a, such that it is parallel to the first branch electrode 160b. The third branch electrode 160d is disposed in the opposite side of the second branch electrode 160c based on the first branch electrode 160b and extends from the first electrode pad 160a toward the fourth side 90 and is bent to extend linearly toward the second side 70 such that it is parallel to the first branch electrode 160b.

The second branch electrode 160c and the third branch electrode 160d are disposed on both sides of the first branch electrode 160b, and the first to third branch electrodes 160b, 160c, and 160d meet at the first electrode pad 160a, such that the first electrode 160 has an overall fork-shaped structure having three branches. In particular, in the present exemplary embodiment, the second branch electrode 160c and the third branch electrode 160d extend from the first electrode pad 160a toward the third side 80 and the fourth side 90, respectively, in a rounded manner (i.e., drawing a curved line) and bent to extend linearly toward the second side 70. In this case, rounded portions of the second branch electrode 160c and the third branch electrode 160d extending from the first electrode pad 160a form a circular arc with the first electrode pad 160a as a center.

As illustrated in FIG. 1, the second electrodes 170 and 170′ include a first sub-electrode 170 and a second sub-electrode 170′ which are separately disposed (not directly connected). The second electrodes 170 and 170′ correspond to p-electrodes in the present exemplary embodiment. The second electrodes 170 and 170′ are disposed in a bilateral symmetry overall with the first branch electrode 160b as a center.

The first sub-electrode 170 having polarity of the p-electrode includes a second electrode pad 170a, a fourth branch electrode 170b, and a fifth branch electrode 170c. In detail, the second electrode pad 170a is disposed in the corner between the second side 70 and the third side 80. The fourth branch electrode 170b extends inwardly (when viewed from the above) from the second electrode pad 170a and is bent to extend linearly toward the first side 60 between the first branch electrode 160b and the second branch electrode 160c. In particular, a linear portion of the fourth branch electrode 170b extends in parallel to the first branch electrode 160b and the second branch electrode 160c. The fifth branch electrode 170c extends linearly from the second electrode pad 170a along the third side 80, and is disposed on an outer side of the second branch electrode 160c of the first electrode 160. In particular, a linear portion of the fifth branch electrode 170c extends in parallel to the second branch electrode 160c. As illustrated in FIG. 1, the two branch electrodes 170b and 170c of the first sub-electrode 170 having p-electrode polarity are disposed to be interdigitated with the first and second branch electrodes 160b and 160c of the first electrode 160.

The second sub-electrode 170′ having p-electrode polarity is symmetrical to the first sub-electrode 170 and includes a third electrode pad 170a′ and sixth and seventh branch electrodes 170b′ and 170c′ extending from the electrode pad 170a′. In detail, the third electrode pad 170a′ having p-electrode polarity is disposed in the corner between the second side 70 and the fourth side 90. The sixth branch electrode 170b′ extends inwardly from the third electrode pad 170a′ and is bent to extend linearly toward the first side 60 between the first branch electrode 160b and the third branch electrode 160d. The seventh branch electrode 170c′ extends linearly from the third electrode pad 170a′ along the fourth side 90 and is disposed on an outer side of the third branch electrode 160d. The two branch electrodes 170b′ and 170c′ of the second sub-electrode 170′ having p-electrode polarity are disposed to be interdigitated with the first and third branch electrodes 160b and 160d of the first electrode 160 having n-electrode polarity. Also, as illustrated in FIG. 2, a passivation layer 78 formed of an insulator such as SiO₂, or the like, may be formed on an upper surface of the semiconductor light emitting device with the first electrode 160 and the second electrodes 170 and 170′ formed thereon. The passivation layer 78 may be formed to cover the entirety of the device, only excluding the electrode pads 160a, 170a, and 170a′ for electrical connection (wire bonding, or the like).

As illustrated in FIG. 1, the first electrode 160 and the second electrodes 170 and 170′ are disposed in a bilateral symmetry with the first branch electrode 160b disposed in a central portion of the upper surface of the light emitting structure as a center. Also, the fourth to seventh branch electrodes 170b, 170c, 170b′, and 170c′ of the second electrodes 170 and 170′ having p-electrode polarity are arranged to be interdigitated with the first to third branch electrodes 160b, 160c, and 160d of the first electrode 160 having n-electrode polarity at substantially the same intervals. Also, the branch electrodes 160b, 160c, 160d of the first electrode 160 and the branch electrodes 170b, 170c, 170b′, and 170c′ of the second electrodes 170 and 170′ are disposed to be parallel in the interdigitated region thereof (overlap region). The arrangement of the branch electrodes in the interdigitated form at equal intervals renders a current to spread evenly, contributing to uniform luminous characteristics. Also, since the second and third electrode pads 170a and 170a′ are disposed at both corners of the side (the second side 70) opposing the first electrode pad 160, current crowding in the two electrode pads 170a and 170a′ may be reduced.

Referring to FIG. 1, an angle (θ) between a line (please refer to the dotted line) formed by connecting a center of the second electrode pad 170a to an end portion Q of the second branch electrode 160c and a line (i.e., a line extending from the linear portion of the second branch electrode 160c) (please refer to the dotted line) extending from the end portion Q of the second branch electrode 160c may range from 40 to 60 degrees. By disposing the second electrode pad 170a within the aforementioned angle range in relation to the end portion Q of the second branch electrode 160c, variations in a current spreading distance c between the branch electrodes having heterogeneous polarities and a current spreading distance in the second electrode pad 170a may be significantly reduced. Also, in a state in which the second electrode pad 170a is disposed within the foregoing angle range, a portion of the fourth branch electrode 170b connected to the second electrode pad 170a is designed as a curve, rather than a line, whereby a current spreading distance between the second electrode pad 170a and the second branch electrode 160c may be maintained to be substantially equal to the current spreading distance c between the branch electrodes. As a result, uniform current spreading characteristics may be secured even in the second electrode pad and a region adjacent thereto, as well as in the overlap regions between the branch electrodes.

Similarly, the third electrode pad 170a′ disposed to be symmetrical with respect to the second electrode pad 170a is also disposed at a position within the foregoing angle range. In detail, an angle (θ) between a line (the dotted line) formed by connecting a center of the third electrode pad 170a′ to an end portion of the third branch electrode 160d and a line (the dotted line) extending from the end portion of the third branch electrode 160d may range from 40 to 60 degrees. Accordingly, uniform current spreading may be secured overall in the overlap regions between the branch electrodes and in the second and third electrode pads and regions adjacent thereto, increasing an effective light emitting area in order to enhance luminance and efficiency.

Referring to FIG. 1, at a middle point P of a segment formed by connecting the end portion Q of the second branch electrode 160c and an end point R of the first branch electrode 160b, the fourth branch electrode 170b may be bent to be curved from the linear line so as to converge into the second electrode pad 170a. Similarly, at a middle point P of a segment formed by connecting the end portion of the third branch electrode 160d and the end point of the first branch electrode 160b, the sixth branch electrode 170b′ may be bent to be curved from the linear line so as to converge into the third electrode pad 170a′. In this manner, by designing the curved and linear structures, uniform current spreading characteristics may be secured in the linear portion or bent portion of the fourth branch electrode 170b and the fifth branch electrode 170b′.

Also, referring to FIG. 1, an angle a between a portion in which the fourth branch electrode 170b is led from the second electrode pad 170a and a portion in which the fifth branch electrode 170c is led from the second electrode pad 170a ranges from 100 to 180 degrees. By maintaining the angle a greater than or equal to 100 degrees, current interference between the two branch electrodes 170b and 170c connected to the second electrode pad 170a may be reduced or prevented. Also, when the angle a exceeds 180 degrees, uniformity of current spreading may not be secured in the connection portion of the second electrode pad 170a and the fourth branch electrode 170b. Similarly, an angle a between a portion in which the sixth branch electrode 170b′ is led from the third electrode pad 170a′ and a portion in which the seventh branch electrode 170c′ is led from the third electrode pad 170a′ ranges from 100 to 180 degrees.

Also, referring to FIG. 1, a distance b between the fifth branch electrode 170c and a lateral outer edge of the light emitting structure adjacent thereto may range from 30% to 50% of the current spreading distance c between the mutually adjacent first to seventh branch electrodes having different polarities. Similarly, a distance b between the seventh branch electrode 170c and a lateral outer edge of the light emitting structure adjacent thereto may range from 30% to 50% of the current spreading distance c between the mutually adjacent first to seventh branch electrodes having different polarities. In this manner, since the distance b is maintained to stay within the range from 30% to 50% of the current spreading distance c between the respective branch electrodes, current density between the outer edge of the chip and the branch electrodes adjacent thereto may be aptly secured and the area between the outer edge of the light emitting device (outer edge of the chip) and the branch electrodes adjacent thereto may be effectively utilized, further enhancing luminous efficiency.

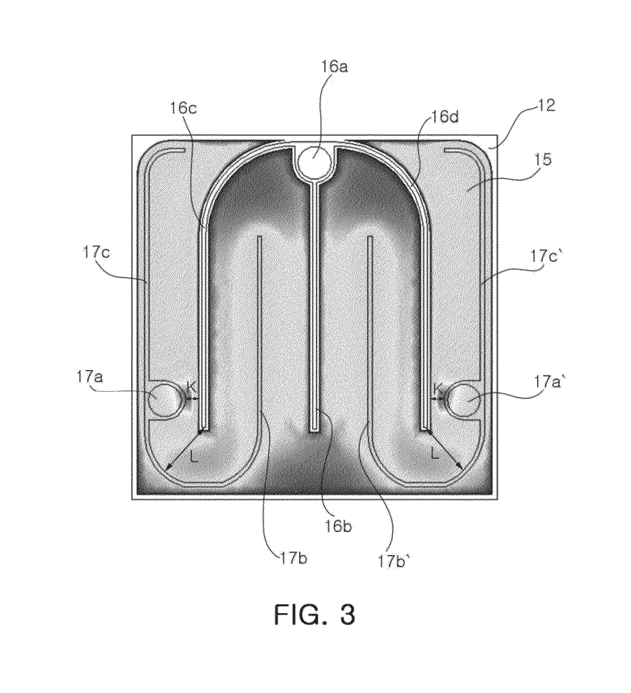

FIG. 3 is a plan view illustrating an electrode structure of a light emitting device according to comparative example. In the light emitting device of FIG. 3, similar to the foregoing embodiment, a p-electrode formed on a transparent electrode layer 15 and connected to a p-type semiconductor layer includes a first electrode pad 16a and first to third branch electrodes 16b, 16c, and 16d. An n-electrode connected to an n-type semiconductor layer 12 includes second and third electrode pads 17a and 17a′ and fourth to seventh branch electrodes 17b, 17c, 17b′, and 17c′. However, unlike the foregoing embodiment, the second and third electrode pads 17a and 17a′ are disposed in the third and fourth sides, rather than in both corners of the second side. Thus, a current spreading distance K in the second and third electrode pads 17a and 17a′ is excessively short, relative to a current spreading distance L in other regions, causing significant current crowding in the vicinity of the second and third electrode pads 17a and 17a′. Also, a region between the fifth branch electrode 17c and the outer edge (outer edge of mesa) of the chip adjacent thereto and a region between the seventh branch electrode 17c′ and the outer edge of the chip adjacent thereto may not be sufficiently utilized as a light emitting area.

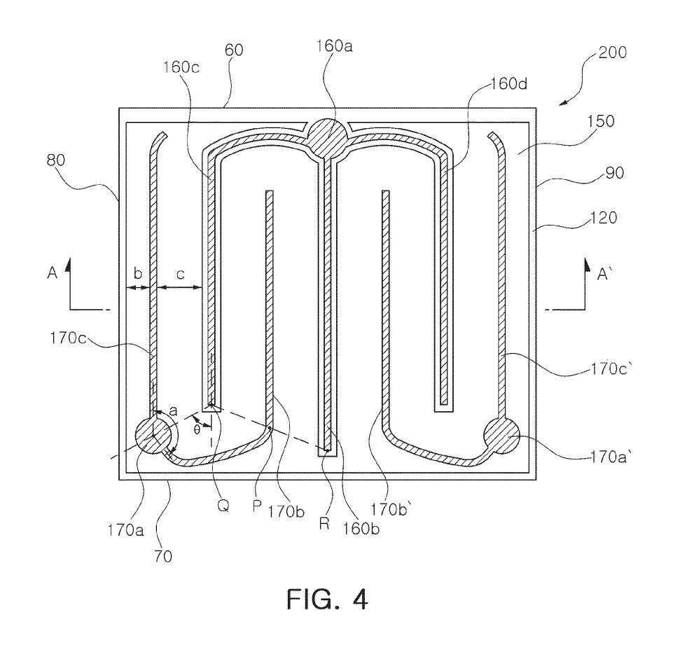

FIG. 4 is a plan view illustrating a semiconductor light emitting device according to another exemplary embodiment of the present disclosure. In the exemplary embodiment of FIG. 4, similar to the foregoing exemplary embodiment (please refer to FIG. 1), the angle (θ) ranges from 40 to 60 degrees. The angle a may range from 100 to 180 degrees. Also, the distance b ranges from 30% to 50% of the current spreading distance b between the branch electrodes. An overall electrode structure may be bilaterally symmetrical based on a first branch electrode 160b.

In the exemplary embodiment of FIG. 4, a second branch electrode 160c and a third branch electrode 160d extending from a first electrode pad 160a, while drawing a curved line, form two different circular arcs connected by the first electrode pad 160a. Such an electrode structure, in particular, renders a current spreading distance in the first electrode pad 160a uniform.

In the exemplary embodiments of FIGS. 1 to 4, the end portion R of the first branch electrode 160b extends toward the second side 70 so as to be closer to the second side 70 than the end portion Q of the second branch electrode 160c and the end portion of the third branch electrode 160d are. This may be advantageous in securing a larger effective light emitting area. Also, as illustrated in FIGS. 1 and 4, the fifth branch electrode 170c and the seventh branch electrode 170c′ are bent inwardly in the vicinity of end portions thereof, obtaining advantages in rendering current spreading characteristics in the end portions of the respective branch electrodes 170c and 170c′ more uniform.

In the exemplary embodiments as described above, the first electrode 160 is an n-electrode and the second electrodes 170 and 170′ are p-electrodes, but polarities of the first electrode and the second electrodes 170 and 170′ maybe interchanged. In the case in which the first electrode 160 is a p-electrode and the second electrodes 170 and 170′ are n-electrodes, the first electrode 160 may be electrically connected to a p-type semiconductor layer on the p-type semiconductor layer and the second electrodes 170 and 170′ may be electrically connected to an n-type semiconductor layer exposed due to mesa etching on the n-type semiconductor layer.

While exemplary embodiments have been shown and described above, it will be apparent to those skilled in the art that modifications and variations could be made without departing from the spirit and scope of the present disclosure as defined by the appended claims.

1. A semiconductor light emitting device comprising:
a light emitting structure including an n-type semiconductor layer, a p-type semiconductor layer, and an active layer interposed therebetween, and having a rectangular upper surface formed with first and second sides opposing one another and third and fourth sides opposing one another;
a first electrode formed on an upper surface of the light emitting structure and connected to one of the n-type semiconductor layer and the p-type semiconductor layer; and
a second electrode formed on the upper surface of the light emitting structure and connected to the other of the n-type semiconductor layer and the p-type semiconductor layer,
wherein the first electrode comprises:
a first electrode pad disposed in a central portion of the first side, a first branch electrode extending linearly from the first electrode pad toward the second side such that it is parallel to the third side; and
second and third branch electrodes extending from the first electrode pad, bent toward the third and fourth sides, and extending toward the second side such that they are parallel to the first branch electrode and disposed on both sides of the first branch electrode, and
the second electrode comprises a second electrode pad disposed in the corner between the second side and the third side; a third electrode pad disposed in the corner between the second side and the fourth side; a fourth branch electrode extending inwardly from the second electrode pad in a bent manner and extending linearly toward the first side between the first and second branch electrodes; a fifth branch electrode extending from the second electrode pad along the third side and disposed in outer side of the second branch electrode; a sixth branch electrode extending inwardly from the third electrode pad in a bent manner and extending linearly toward the first side between the first and third branch electrodes; and a seventh branch electrode extending from the third electrode pad along the fourth side and disposed in an outer side of the third branch electrode.

2. The semiconductor light emitting device of claim 1, wherein the fourth to seventh branch electrodes of the second electrode are disposed to be interdigitated with the first to third branch electrodes of the first electrode at substantially the same intervals therebetween.

3. The semiconductor light emitting device of claim 1, wherein the first and second electrodes are disposed to be symmetrical based on the first branch electrode.

4. The semiconductor light emitting device of claim 1, wherein a line formed by connecting a center of the second electrode pad and an end portion of the second branch electrode is at an angle ranging from 40 to 60 degrees with respect to a line extending from an end portion of the second branch electrode, and
a line formed by connecting a center of the third electrode pad and an end portion of the third branch electrode is at an angle ranging from 40 to 60 degrees with respect to a line extending from an end portion of the third branch electrode.

5. The semiconductor light emitting device of claim 1, wherein the fourth branch electrode is bent to be curved from a linear line at a middle point of a segment formed by connecting the end portion of the second branch electrode and an endpoint of the first branch electrode, and
the sixth branch electrode is bent to be curved from a linear line at a middle point of a segment formed by connecting the end portion of the third branch electrode and an end point of the first branch electrode.

6. The semiconductor light emitting device of claim 1, wherein a portion in which the fourth branch electrode is led from the second electrode pad is at an angle ranging from 100 to 180 degrees with respect to a portion in which the fifth branch electrode is led from the second electrode pad, and
a portion in which the sixth branch electrode is led from the third electrode pad is at an angle ranging from 100 to 180 degrees with respect to a portion in which the seventh branch electrode is led from the third electrode pad.

7. The semiconductor light emitting device of claim 1, wherein a distance between the fifth branch electrode and a lateral outer edge of the light emitting structure ranges from 30% to 50% of a current spreading distance between the mutual first to seventh branch electrodes having different polarities, and
a distance between the seventh branch electrode and a lateral outer edge of the light emitting structure ranges from 30% to 50% of a current spreading distance between the mutual first to seventh branch electrodes having different polarities.

8. The semiconductor light emitting device of claim 1, wherein the second and third branch electrodes extend, while drawing a curved line, from the first electrode pad toward the third and fourth sides, respectively, are bent, and extend linearly toward the second side.

9. The semiconductor light emitting device of claim 8, wherein the rounded portions of the second and third branch electrodes extending from the first electrode pad form a circular arc based on the first electrode pad.

10. The semiconductor light emitting device of claim 8, wherein the rounded portions of the second and third branch electrodes extending from the first electrode pad form two different circular arcs connected by the first electrode pad.

11. The semiconductor light emitting device of claim 1, wherein the end portion of the first branch electrode extends toward the second side so as to be closer to the second side than the end portions of the second and third branch electrodes are.

12. The semiconductor light emitting device of claim 1, wherein the fifth and seventh branch electrodes are bent inwardly in the vicinity of end portions thereof.

13. The semiconductor light emitting device of claim 1, wherein the first electrode is an n-electrode, and the second electrode is a p-electrode.

14. The semiconductor light emitting device of claim 1, wherein the semiconductor light emitting device is a nitride-based semiconductor light emitting device.
